(19) United States
(12) Patent Application Publication
(10) Pub. No.: US 2026/0223408 A1
(43) Pub. Date: Jul. 30, 2026

(54) SEMICONDUCTOR DEVICE, ARRAY SUBSTRATE, AND DISPLAY PANEL

(71) Applicant: Guangzhou China Star Optoelectronics Semiconductor Display Technology Co., LTd., Guangzhou (CN)

(72) Inventors: Juncheng XIAO, Guangzhou (CN); Shan LI, Guangzhou (CN); Weiran CAO, Guangzhou (CN); Jun ZHAO, Guangzhou (CN); Mingjiue YU, Guangzhou (CN); Xiaoxing ZHANG, Guangzhou (CN)

(73) Assignee: Guangzhou China Star Optoelectronics Semiconductor Display Technology Co., LTd., Guangzhou (CN)

(21) Appl. No.: 19/224,796

(22) Filed: May 31, 2025

(30) Foreign Application Priority Data
Jan. 24, 2025 (CN) 202510120882.3

(51) Int. Cl. H10D 30/67; H10D 86/40; H10D 86/60; H10K 59/121

(52) U.S. Cl. CPC H10D 30/6755; H10D 30/6731; H10D 30/6732; H10D 30/6757; H10D 86/423; H10D 86/60; H10K 59/1213

(57) ABSTRACT

A semiconductor device, an array substrate, and a display panel are provided. The semiconductor device includes an active layer; a gate disposed on a side of the active layer; and a source and a drain respectively connected to opposite ends of the active layer. The active layer comprises one or more first sublayers, each of the first sublayers includes a metal oxide conductive material and an electrical regulating element doped in the metal oxide conductive material. The electrical regulating element includes at least one of Group VIII metal elements.

### CROSS REFERENCE TO RELATED APPLICATIONS

This application claims priority to Chinese Patent Application No. 202510120882.3 filed on Jan. 24, 2025, the entire disclosure of which is incorporated herein by reference in their entirety.

### TECHNICAL FIELD

The present disclosure relates to the field of display technologies, and more particularly, to a semiconductor device, an array substrate, and a display panel.

### BACKGROUND

Oxide semiconductor thin film transistors have attracted wide attention due to their advantages such as high electron mobility, excellent uniformity, good transparency, and low cost.

For example, indium gallium zinc oxide (IGZO) semiconductor materials have been in mass production phase. However, at present, it is difficult to realize a thin film transistor device having a higher mobility due to material and process limitations of the oxide semiconductor material.

### SUMMARY

Embodiments of the present disclosure provide a semiconductor device, an array substrate, and a display panel, which can improve the mobility of an active layer and the charging efficiency of the semiconductor device.

Some embodiments of the present disclosure provide a semiconductor device including:
an active layer;
a gate disposed on a side of the active layer; and
a source and a drain respectively connected to opposite ends of the active layer.

The active layer includes one or more first sublayers, each of the first sublayers includes a metal oxide conductive material and an electrical regulating element doped in the metal oxide conductive material, and the electrical regulating element includes at least one of Group VIII metal elements.

In some embodiments of the present disclosure, the metal oxide conductive material includes at least one of indium tin oxide, antimony tin oxide, fluorine-doped tin oxide, aluminum-doped zinc oxide, gallium-doped zinc oxide, or indium-doped zinc oxide.

In some embodiments of the present disclosure, the metal oxide conductive material is doped with at least one of an elemental substance of the electrical regulating element or a compound of the electrical regulating element.

In some embodiments of the present disclosure, the metal oxide conductive material is doped with at least one of an elemental substance of the electrical regulating element or an oxide of the electrical regulating element.

In some embodiments of the present disclosure, the metal oxide conductive material is doped with at least one of iron element or iron oxide.

In some embodiments of the present disclosure, the active layer includes a channel, and a first contact portion and a second contact portion located on opposite ends of the channel; the gate is disposed opposite to the channel, the source is connected to the first contact portion, and the drain is connected to the second contact portion; and the electrical regulating element is distributed in the channel, the first contact portion, and the second contact portion.

In some embodiments of the present disclosure, the channel, the first contact portion, and the second contact portion are all semiconductors.

The semiconductor device further includes:
a substrate on which the gate is disposed;
a first gate insulating layer disposed on the substrate and covering the gate, wherein the active layer is disposed on a side of the first gate insulating layer away from the gate, an orthographic projection of at least the channel on the substrate is located in an orthographic projection of the gate on the substrate, and the source and the drain are disposed on a side of the first gate insulating layer away from the substrate and respectively connected to the first contact portion and the second contact portion.

In some embodiments of the present disclosure, the channel is a semiconductor, and the first contact portion and the second contact portion are conductors; and
the material of the channel includes the metal oxide conductive material and the electrical regulating element doped in the metal oxide conductive material, and the material of the first contact portion and the second contact portion each includes the metal oxide conductive material, and the electrical regulating element and a conductive element doped in the metal oxide conductive material.

In some embodiments of the present disclosure, the semiconductor device further includes:
a substrate on which the active layer is disposed; and
a second gate insulating layer disposed on a side of the active layer away from the substrate and covering the active layer, wherein the gate is disposed on a side of the second gate insulating layer away from the active layer and the source and the drain are disposed on a side of the second gate insulating layer away from the active layer and respectively connected to the first contact portion and the second contact portion.

In some embodiments of the present disclosure, a ratio of metal atoms of the electrical regulating element in the one or more first sublayers is greater than or equal to 0.1% and less than or equal to 10%.

In some embodiments of the present disclosure, a carrier concentration of the one or more first sublayers is greater than or equal to 1E14 cm⁻³ and less than or equal to 5E19 cm-3;

a resistance of the one or more first sublayers is greater than or equal to 1E4 Ω/□ and less than or equal to 1E10 Ω/□; and

a Hall mobility of the one or more first sublayers is greater than or equal to 30 cm²/V•s and less than or equal to 70cm² /V•s.

In some embodiments of the present disclosure, the active layer further includes one or more second sublayers, the one or more second sublayers and the one or more first sublayers are stacked, and each of the second sublayers includes a metal oxide semiconductor material.

In some embodiments of the present disclosure, a Hall mobility of the one or more second sublayers is less than a Hall mobility of the one or more first sublayers.

In some embodiments of the present disclosure, the active layer includes more than one second sublayer, and one of the first sublayers is disposed between two adjacent second sublayers.

In accordance with the above object of the present disclosure, some embodiments of the present disclosure further provide an array substrate including the semiconductor device described above.

In accordance with the above object of the present disclosure, some embodiments of the present disclosure further provide a display panel including the array substrate described above.

The present disclosure provides the semiconductor device, the array substrate, and the display panel, in which, by adding the electrical regulating element in the metal oxide conductive material of the active layer, a defect state in the metal oxide conductive material can be reduced, thereby converting the metal oxide conductive material into a semiconductor material. At the same time, since the doped metal oxide conductive material has a high electron concentration, the active layer can be enabled to have a high mobility, thereby improving the charging efficiency of the semiconductor device.

Other features and advantages of the present disclosure will be described in detail as follows.

### BRIEF DESCRIPTION OF THE DRAWINGS

In order to clearly explain the technical solutions in the embodiments of the present disclosure, the drawings will be briefly described below. It is apparent that the drawings described as follows are merely some embodiments of the present disclosure, and other drawings may be obtained by those skilled in the art based on these drawings without involving any inventive effort.

For a more complete understanding of the present disclosure and its beneficial effects the following description will be made in conjunction with the accompanying drawings, in which same reference numerals in the following description designate same parts.

FIG. 1 is a schematic diagram of a structure of a semiconductor device according to some embodiments of the present disclosure.

FIG. 2 is a schematic diagram of a structure of an active layer according to some embodiments of the present disclosure.

FIG. 3 is a schematic diagram of another structure of an active layer according to some embodiments of the present disclosure.

FIG. 4 is a schematic diagram of another structure of a semiconductor device according to some embodiments of the present disclosure.

FIG. 5 is a schematic planar diagram of an array substrate according to some embodiments of the present disclosure.

FIG. 6 is a schematic diagram of a display panel according to some embodiments of the present disclosure.

### LIST OF REFERENCE NUMERALS

10. Semiconductor device; 11. Active layer; 111. Channel; 112. First contact portion; 113. Second contact portion; 114. First sublayer; 115. Second sublayer; 12. Gate; 13. Source; 14. Drain; 101. Pixel arrangement area; 102. Non-pixel arrangement area; 1021. Driving circuit sub-region; 21. Substrate; 22. First gate insulating layer; 23. First insulating layer; 24. Barrier layer; 25. Second gate insulating layer; 26. Interlayer dielectric layer; 27. Second insulating layer; 31. Light shielding layer; 40. Display panel; 400. Array substrate.

### DETAILED DESCRIPTION

The technical solutions in the embodiments of the present disclosure will be described below with reference to the accompanying drawings. It will be apparent that the described embodiments are only some of the embodiments of the present disclosure, rather than all embodiments thereof. All other embodiments obtained by a person skilled in the art without involving any inventive effort, based on the embodiments in the present disclosure, fall within the scope of the present disclosure.

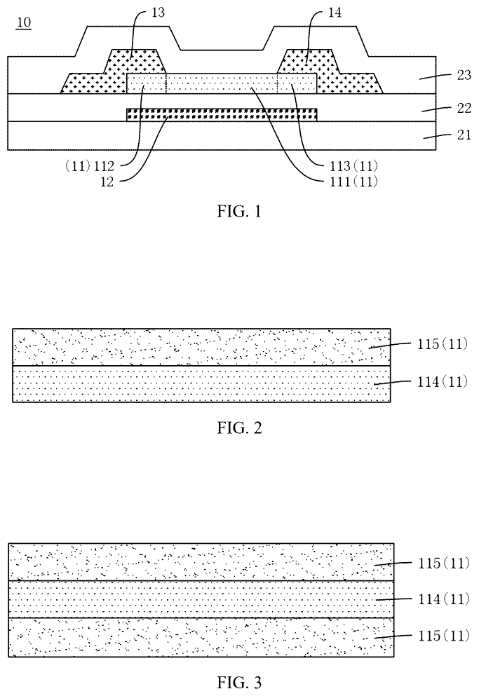

Referring to FIGS. 1 and 2, some embodiments of the present disclosure provide a semiconductor device 10, which includes an active layer 11, a gate 12, a source 13, and a drain 14. The gate 12 is disposed on a side of the active layer 11. The source 13 and the drain 14 are connected to opposite ends of the active layer 11, respectively.

The active layer 11 includes one or more first sublayers 114. Each of the first sublayers 114 comprises a metal oxide conductive material and an electrical regulating element doped in the metal oxide conductive material. The electrical regulating element includes at least one of the Group VIII metal elements.

During the implementation and application process, the embodiments of the present disclosure, by doping the electrical regulating element in the metal oxide conductive material in the active layer 11, can reduce a defect state of the metal oxide conductive material to thereby convert the metal oxide conductive material into a semiconductor material. Meanwhile, since the metal oxide conductive material has a high electron concentration, the active layer 11 can have a high mobility, thereby improving the charging efficiency of the semiconductor device 10. At the same time, according to the embodiments of the present disclosure, by doping the metal oxide conductive material with the electrical regulating element, the defect state in the metal oxide conductive material can be reduced, so that the illumination stability of the active layer 11 can be improved, and the phenomenon that the threshold voltage Vth is negatively biased due to illumination of the active layer 11 can be alleviated.

Specifically, please continue to refer to FIGS. 1 and 2, the semiconductor device 10 is a thin film transistor. In the semiconductor device 10, the active layer 11 includes a channel 111, the first contact portion 112 and the second contact portion 113 that are located on opposite ends of the channel 111. The gate 12 is opposite to the channel 111 of the active layer 11. The source 13 is connected to the first contact portion 112, and the drain 14 is connected to the second contact portion 113.

At least the channel 111 is a semiconductor. By controlling the voltage applied to the gate 12, it is possible to control whether the channel 111 establishes a current passage or not. When the channel 111 establishes the current passage, the first contact portion 112 and the second contact portion 113 are electrically connected with each other, and then the source 13 and the drain 14 are electrically connected to achieve signal transmission.

In some embodiments, the semiconductor device 10 may further include a substrate 21 for supporting the active layer 11, the gate 12, the source 13, and the drain 14, and one or more insulating layers disposed between adjacent two of the layers described above.

In some embodiments, referring to FIG. 1, the semiconductor device 10 may include the substrate 21, the gate 12 disposed on the substrate 21, a first gate insulating layer 22 disposed on the substrate 21 and covering the gate 12, the active layer 11 disposed on a side of the first gate insulating layer 22 away from the gate 12, the source 13 and the drain 14 disposed on a side of the first gate insulating layer 22 away from the substrate 21, and a first insulating layer 23 disposed on the first gate insulating layer 22 and covering the active layer 11, the source 13 and the drain 14. The source 13 and the drain 14 are connected to the first contact portion 112 and the second contact portion 113, respectively.

In some embodiments, the active layer 11 includes one or more first sublayers 114 Each of the first sublayers 114 comprises a metal oxide conductive material and an electrical regulating element doped in the metal oxide conductive material, and the electrical regulating element includes at least one of Group VIII metal elements. The Group VIII metal elements have a strong bonding ability with an oxygen atom. Doping the metal oxide conductive material with the electrical regulating element can reduce a defect state of the metal oxide conductive material to convert the metal oxide conductive material into a semiconductor material. Meanwhile, since the metal oxide conductive material has a high electron concentration, the active layer can have a high mobility, thereby improving the charging efficiency of the semiconductor device 10. At the same time, according to the embodiments of the present disclosure, the doping with the electrical regulating element can reduce the defect state in the metal oxide conductive material, so that the illumination stability of the active layer 11 can be improved, the phenomenon that the threshold voltage Vth is negatively biased due to illumination of the active layer 11 can be alleviated, and the sub-threshold swing of the semiconductor device 10 can be improved.

The electrical regulating element may be distributed in the channel 111, the first contact portion 112, and the second contact portion 113. That is, the electrical regulating element may be uniformly distributed in the first sublayer 114, and the channel 111, the first contact portion 112, and the second contact portion 113 are all semiconductor.

In some embodiments, an orthographic projection of the channel 111 on the substrate 21 is within an orthographic projection of the gate 12 on the substrate 21. Further, an orthographic projection of the first contact portion 112 on the substrate 21 and an orthographic projection of the second contact portion 113 on the substrate 21 both overlap with a part of the orthographic projection of the gate 12 on the substrate 21.

In some embodiments, the metal oxide conductive material includes at least one of indium tin oxide (ITO), antimony tin oxide (ATO), fluorine-doped tin oxide (FTO), aluminum-doped zinc oxide (AZO), gallium-doped zinc oxide (GZO), or indium-doped zinc oxide (IZO). The electrical regulating element may include at least one of iron, cobalt, nickel, ruthenium, rhodium, palladium, osmium, iridium, or platinum.

In some embodiments, the metal oxide conductive material is doped with at least one of an elemental substance of the electrical regulating element or a compound of the electrical regulating element.

In some embodiments, the metal oxide conductive material is doped with at least one of an elemental substance of the electrical regulating element or an oxide of the electrical regulating element. For example, when the electrical regulating element is iron, the metal oxide conductive material is doped with at least one of an iron element or an iron oxide.

In some embodiments, a metal atomic ratio of the electrical regulating element in the first sublayer 114 is greater than or equal to 0.1% and less than or equal to 10%. For example, the metal atomic ratio of the electrical regulating element in the first sublayer 114 may be 0.1%, 1%, 2%, 3%, 4%, 5%, 6%, 7%, 8%, 9%, or 10%.

It is to be understood that the metal atomic ratio described above refers to an atomic ratio of the number of the electrical regulating element to the number of all the metal atoms in the first sublayer 114.

In some embodiments, a carrier concentration in the first sublayer 114 is greater than or equal to 1E14 cm⁻³ and less than or equal to 5E19 cm⁻³. It is to be understood that when the carrier concentration in the film layer is too high, for example, in a range of 1E20 cm⁻³ to 1E21 cm⁻³, the film layer is conductive. According to the embodiments of the present disclosure, the carrier concentration can be reduced by adjusting the ratio of the electrical regulating element in the metal oxide conductive material with a high carrier concentration, so that the conductive material may be converted into a semiconductor.

Note that 1E14 cm⁻³ refers to 1*1014cm⁻³ , and 5E19 cm⁻³ refers to 5*1019cm⁻³.

In some embodiments, a resistance of the first sublayer 114 is greater than or equal to 1E4Ω/□ and less than or equal to 1E10Ω/□. Note that the resistance described above refers to a sheet resistance (i.e., a resistance value per unit area), and 14Ω/□ refers to 1*104Ω/m², and 1E10Ω/□ refers to 1*1010Ω/m².

In some embodiments, a Hall mobility of the first sublayer 114 is greater than or equal to 30 cm² /Vs and less than or equal to 70 cm² /V•s. It is to be understood that when the Hall mobility of the film layer is too high, for example, greater than 100 cm² /(V•s), the film layer is conductive. The Hall mobility of the first sublayer 114 provided in the embodiments of the present disclosure is within 30 cm² /V•s to 70 cm² /V•s, indicating that the first sublayer 114 has a semiconductor characteristic.

According to the embodiments of the present disclosure, a semiconductor material having a higher carrier concentration and a higher mobility can be obtained by doping the metal oxide conductive material with the electrical regulating element, thereby obtaining the active layer 11 having a high mobility.

In some embodiments, referring to FIGS. 2 and 3 the active layer 11 may include or more second sublayers 115. The one or more second sublayers 115 and the one or more first sublayers 114 are stacked. Each of the second sublayers 115 comprises a metal oxide semiconductor material.

The Hall mobility of the second sublayer 115 is less than the Hall mobility of the first sublayer 114. The second sublayer 115 may comprise Indium Gallium Zinc Oxide (IGZO).

Further, when the active layer 11 includes one first sublayer 114 and one second sublayer 115 that are stacked, the first sublayer 114 may be located between the second sublayer 115 and the first gate insulating layer 22, or the second sublayer 115 may be located between the first sublayer 114 and the first gate insulating layer 22. In this case, the second sublayer 115 is disposed on at least one side of the active layer 11, and the second sublayer 115 is made of a metal oxide semiconductor material, so that the second sublayer 115 in the active layer 11 is in contact with the other film layers, thereby facilitating the reduction of defects of the contact interface between the active layer 11 and its adjacent film layers, improving the stability of the semiconductor device 10, and avoiding negative bias of the threshold voltage Vth of the semiconductor device 10, and further improving the performance and reliability of the semiconductor device 10. On the other hand, by adding the second sublayer 115 to the active layer 11, it is beneficial to reduce the thickness of the first sublayer 114, thereby advantageously reducing the overall thickness of the active layer 11 having a high mobility, avoiding negative bias of the threshold voltage Vth caused by excessive thickness of the active layer 11, and further improving the stability of the semiconductor device 10.

In some embodiments, referring to FIGS. 1 and 3, when the active layer 11 includes a plurality of the second sublayers 115, one of the first sublayers 114 is located between two adjacent second sublayers 115, so that the second sublayers 115, both of which are made of a metal oxide semiconductor material, in the active layer 11 are in contact with the adjacent layers, thereby reducing defect states in the contact interfaces between the active layer 11 and the adjacent layers, improving stability of the semiconductor device 10, avoiding negative bias of the threshold voltage Vth of the semiconductor device 10, and further improving performance and reliability of the semiconductor device 10.

It is to be noted that the semiconductor device 10 as shown in FIG. 1 is a thin film transistor device having a bottom gate structure, and the semiconductor device 10 of the embodiments of the present disclosure may also be a thin film transistor device having a top gate structure, as will be described in the following context.

As shown in FIGS. 2 to 4, in another embodiment of the present disclosure, the semiconductor device 10 may include a substrate 21, a light shielding layer 31 disposed on the substrate 21, a barrier layer 24 disposed on the substrate 21 and covering the light shielding layer 31, an active layer 11 disposed on the barrier layer 24, a second gate insulating layer 25 disposed on a side of the active layer 11 away from the substrate 21 and covering a part of the active layer 11, a gate 12 disposed on a side of the second gate insulating layer 25 away from the channel 111, an interlayer dielectric layer 26 covering the active layer 11, the second gate insulating layer 25 and the gate 12, a source 13 and a drain 14 disposed on a side of the interlayer dielectric layer 26 away from the active layer 11, and a second insulating layer 27 disposed on the interlayer dielectric layer 26 and covering the source 13 and the drain 14. The source 13 and the drain 14 are connected to the first contact portion 112 and the second contact portion 113 through the interlayer dielectric layer 26, respectively.

The second gate insulating layer 25 covers at least the channel 111. The gate 12 is located on a side of the second gate insulating layer 25 away from the channel 111, the source 13 is connected to the first contact portion 112 penetrating through the interlayer dielectric layer 26, and the drain 14 is connected to the second contact portion 113 penetrating through the interlayer dielectric layer 26.

In the present embodiments, the active layer 11 comprises one or more first sublayers 114. Each of the sublayers 114 comprises a metal oxide conductive material and an electrical regulating element doped in the metal oxide conductive material. The electrical regulating element comprises at least one elements of Group VIII metal elements. Doping the metal oxide conductive material with the electrical regulating element can reduce a defect state in the metal oxide conductive material and can be converted into a semiconductor material. Meanwhile, since the metal oxide conductive material has a high electron concentration, the active layer can have a high mobility, thereby improving the charging efficiency of the semiconductor device 10. At the same time, according to the embodiments of the present disclosure, by doping the metal oxide conductive material with the electrical regulating element, the defect state of the metal oxide conductive material can be reduced, so that the illumination stability of the active layer 11 can be improved, and the phenomenon that the threshold voltage Vth is negatively biased due to illumination of the active layer 11 can be alleviated.

In some embodiments, the channel 111 includes the metal oxide conductive material and the electrical regulating element doped in the metal oxide conductive material, and the channel 111 becomes a semiconductor. The first contact portion 112 and the second contact portion 113 each include the metal oxide conductive material, and the electrical regulating element and a conductive element doped in the metal oxide conductive material. The conductive element is added into the first contact portion 112 and the second contact portion 113, so that the semiconductor is converted into a conductor, thereby realizing electrical connection between the first contact portion 112 and the source 13 and between the second contact portion 113 and the drain 14.

In some embodiments, the conductive element includes at least one of B, Ne, P, or A

In the manufacturing process of the semiconductor device 10, the elemental substance or oxide of the electrical regulating element may be mixed with the metal oxide conductive material, and then deposited to obtain the active layer 11, so that the electrical regulating element may be uniformly distributed in the active layer 11. Next, the regions corresponding to the first contact portion 112 and the second contact portion 113 in the active layer 11 may be subjected to a conductive treatment, for example, an ion implantation process.

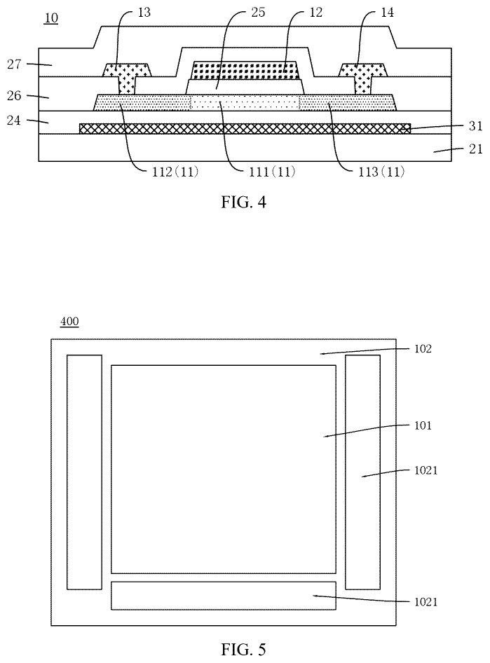

It is to be noted that, in the embodiment shown in FIG. 4, the second sublayer 115 may also be provided for the active layer 11, and the structures and positions of the first sublayer 114 and the second sublayer 115 in the active layer 11 according to the embodiment shown in FIG. 4 may be the same as those in the embodiment shown in FIG. 1, and details are not repeated herein. Moreover, in the embodiment shown in FIG. 4, the first sublayer 114 and the second sublayer 115 may be doped with a conductive element at positions corresponding to the first contact portion 112 and the second contact portion 113 to perform a conductive process.

In summary, according to the embodiments of the present disclosure, by doping the metal oxide conductive material with the electrical regulating element in the active layer 11, the defect state in the metal oxide conductive material can be reduced, and the metal oxide conductive material becomes a semiconductor material. Meanwhile, since the metal oxide conductive material has a high electron concentration, the active layer can have a high mobility, thereby improving the charging efficiency of the semiconductor device 10. Moreover, according to the embodiments of the present disclosure, by doping the metal oxide conductive material with the electrical regulating element, the defect state in the metal oxide conductive material can be reduced, the illumination stability of the active layer 11 can be improved, and the phenomenon that the threshold voltage Vth is negatively biased due to illumination of the active layer 11 can be alleviated.

Referring to FIGS. 1 and 5, some embodiments of the present disclosure further provide an array substrate 400 including the semiconductor device 10 described in the above embodiments.

In some embodiments, the array substrate 400 includes a pixel arrangement region 101 and a non-pixel arrangement region 102 adjacent to the pixel arrangement region 101. The non-pixel arrangement region 102 includes one or more driving circuit sub-regions 1021. A plurality of pixel circuits are disposed in the pixel arrangement region 101 of the array substrate, and electrical members such as functional circuits and signal traces are disposed in the non-pixel arrangement region 102 of the array substrate. For example, functional circuits such as gate driving circuits and multiplexed circuits may be provided in the driving circuit sub-regions 1021 of the non-pixel arrangement region 102.

The semiconductor device 10 may be used in at least the gate driving circuits and the multiplexing circuits to form a thin film transistor having a high mobility in the gate driving circuits and the multiplexing circuits, thereby improving the performance and the electrical signal transmission capability of the gate driving circuits and the multiplexing circuits.

In some embodiments, the array substrate further includes scan signal lines. One end o f each scan signal line is connected to the gate driving circuit, the other end of the scan signal line extends into the pixel arrangement region 101 to be connected to the pixel circuit. The gate driving circuit includes an output transistor connected to the scan signal line. The output transistor in at least the gate driving circuit is the semiconductor device 10 to satisfy signal output efficiency of the output transistor. Further, all thin film transistors in the gate driving circuits may be the semiconductor device 10. For example, the gate driving circuit may include a pull-up control module, a pull-up module, a pull-down module, and a pull-down maintenance module. The thin film transistors in the pull-up control module, the pull-up module, the pull-down module, and the pull-down maintenance module may all be the semiconductor device 10.

In some embodiments, the thin film transistors in the pixel circuits may also be the semiconductor device 10.

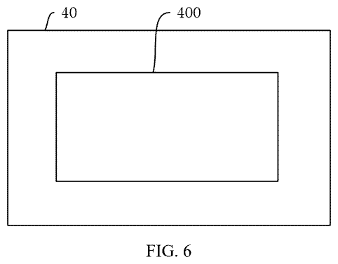

Referring to FIGS. 1 and 6, some embodiments of the present disclosure further provide a display panel 40 including the array substrate 400 described in the above embodiments.

In some embodiments, the display panel 40 may be an organic light-emitting diode display panel. Further, the display panel 40 may include film layers such as an anode layer, an organic light emitting layer, a cathode layer, and an encapsulation layer disposed on the array substrate 400.

In some embodiments, the display panel 40 may be a liquid crystal display panel. Further, the display panel includes a pixel electrode disposed on the array substrate 400, a liquid crystal layer disposed on a side of the pixel electrode away from the array substrate 400, a color film substrate disposed on a side of the liquid crystal layer away from the array substrate 400, and a common electrode disposed on the array substrate 400 and/or on the color film substrate.

It is to be understood that the display panel 40 contains the array substrate 400 and the semiconductor device 10, which are the same as those in the above-described embodiments. Therefore, the display panel 40 may have the same beneficial effects as those in the above-described embodiments, and details are not described herein.

Here, the mobility is one of the important indexes for measuring the semiconductor device 10, and it determines the speed, at which the charge moves in the semiconductor device 10. High mobility means a faster response speed and a higher operating efficiency, which is essential for improving the overall performance of the electronic device. Meanwhile, the larger the mobility, the smaller the resistivity, and the smaller the power consumption by the same current, indicating that the semiconductor device 10 with high mobility can perform the same task with lower power consumption, thereby reducing energy waste and fever. Moreover, the mobility directly affects the switching speed and the cutoff frequency of the semiconductor device 10, so that the semiconductor device 10 having a high mobility can shorten the time for a few carriers to cross the base region, thereby improving the switching speed and the frequency response characteristic of the semiconductor device 10.

In the embodiments of the present disclosure, the semiconductor device 10 provided in the embodiments has high mobility and illumination stability, and it is advantageous to improve the response speed, operation efficiency, and stability of the display panel 40, and power consumption of the display panel 40 can be reduced.

In the description of the present disclosure, the terms “first” and “second” are used for descriptive purposes only and are not to be construed as indicating or implying relative importance or implying the number of indicated technical features. Therefore, the features defined as “first” and “second” may explicitly or implicitly include one or more features. In the description of the present disclosure, “plurality” means two or more, unless otherwise explicitly defined.

In the above embodiments, the description of each embodiment has its own emphasis, and parts not described in detail in a certain embodiment may be referred to the related description of other embodiments.

Related technical features in the examples and the embodiments of the present disclosure may be combined and replaced with each other without conflict.

The above description is only used for preferred embodiments of the present disclosure, and does not constitute any form of limitation to the present disclosure. However, any simple modifications, equivalent variations and modifications made to the above embodiments in accordance with the technical essence of the present disclosure, without departing from the technical solutions of the present disclosure, still fall within the scope of the present disclosure.

What is claimed is:

1. A semiconductor device, comprising:
an active layer;
a gate disposed on a side of the active layer; and
a source and a drain respectively connected to opposite ends of the active layer;
wherein the active layer comprises one or more first sublayers, each of the first sublayers comprises a metal oxide conductive material and an electrical regulating element doped in the metal oxide conductive material, and the electrical regulating element comprises at least one of Group VIII metal elements.

2. The semiconductor device according to claim 1, wherein the metal oxide conductive material comprises at least one of indium tin oxide, antimony tin oxide, fluorine-doped tin oxide, aluminum-doped zinc oxide, gallium-doped zinc oxide, or indium-doped zinc oxide.

3. The semiconductor device according to claim 1, wherein the metal oxide conductive material is doped with at least one of an elemental substance of the electrical regulating element or a compound of the electrical regulating element.

4. The semiconductor device according to claim 3, wherein the metal oxide conductive material is doped with at least one of an elemental substance of the electrical regulating element or an oxide of the electrical regulating element.

5. The semiconductor device according to claim 3, wherein the metal oxide conductive material is doped with at least one of iron element or iron oxide.

6. The semiconductor device according to claim 1, wherein the active layer comprises a channel, and a first contact portion and a second contact portion located on opposite ends of the channel, the gate is disposed opposite to the channel, the source is connected to the first contact portion, the drain is connected to the second contact portion, and the electrical regulating element is distributed in the channel, the first contact portion, and the second contact portion.

7. The semiconductor device according to claim 6, wherein the channel, the first contact portion, and the second contact portion are all semiconductors; and
the semiconductor device further comprises:
a substrate on which the gate is disposed; and
a first gate insulating layer disposed on the substrate and covering the gate, wherein the active layer is disposed on a side of the first gate insulating layer away from the gate, an orthographic projection of at least the channel on the substrate is located in an orthographic projection of the gate on the substrate, and the source and the drain are disposed on a side of the first gate insulating layer away from the substrate and respectively connected to the first contact portion and the second contact portion.

8. The semiconductor device according to claim 6, wherein the channel is a semiconductor, and the first contact portion and the second contact portion are conductors; and
the channel comprises the metal oxide conductive material and the electrical regulating element doped in the metal oxide conductive material, and the first contact portion and the second contact portion each comprise the metal oxide conductive material, and the electrical regulating element and a conductive element doped in the metal oxide conductive material.

9. The semiconductor device according to claim 8, further comprising:
a substrate on which the active layer is disposed; and
a second gate insulating layer disposed on a side of the active layer away from the substrate and covering the active layer, wherein the gate is disposed on a side of the second gate insulating layer away from the active layer, and the source and the drain are disposed on a side of the second gate insulating layer away from the active layer and respectively connected to the first contact portion and the second contact portion.

10. The semiconductor device according to claim 1, wherein a ratio of metal atoms of the electrical regulating element in the one or more first sublayers is greater than or equal to 0.1% and less than or equal to 10%.

11. The semiconductor device according to claim 1, wherein a carrier concentration of the one or more first sublayers is greater than or equal to 1E14 cm⁻³ and less than or equal to 5E19 cm⁻³;
a resistance of the one or more first sublayers is greater than or equal to 1E4 Ω/□ and less than or equal to 1E10 Ω/□; and
a Hall mobility of the one or more first sublayers is greater than or equal to 30 cm²/V•s and less than or equal to 70 cm²/V•s.

12. The semiconductor device according to claim 1, wherein the active layer further comprises one or more second sublayers, the one or more second sublayers and the one or more first sublayers are stacked, and each of the second sublayers comprises a metal oxide semiconductor material.

13. The semiconductor device according to claim 12, wherein a Hall mobility of the one or more second sublayers is less than a Hall mobility of the one or more first sublayers.

14. The semiconductor device according to claim 12, wherein the active layer comprises more than one second sublayer, and one of the first sublayers is disposed between two adjacent second sublayers.

15. An array substrate comprising a semiconductor device, wherein the semiconductor device comprises:
an active layer;
a gate disposed on a side of the active layer; and
a source and a drain respectively connected to opposite ends of the active layer;
wherein the active layer comprises one or more first sublayers, each of the first sublayers comprises a metal oxide conductive material and an electrical regulating element doped in the metal oxide conductive material, and the electrical regulating element comprises at least one of Group VIII metal elements.

16. The array substrate according to claim 15, wherein the active layer comprises a channel, and a first contact portion and a second contact portion located on opposite ends of the channel, the gate is disposed opposite to the channel, the source is connected to the first contact portion, the drain is connected to the second contact portion, and the electrical regulating element is distributed in the channel, the first contact portion, and the second contact portion.

17. The array substrate according to claim 16, wherein the channel, the first contact portion, and the second contact portion are all semiconductors; and
the semiconductor device further comprises:
a substrate on which the gate is disposed; and
a first gate insulating layer disposed on the substrate and covering the gate, wherein the active layer is disposed on a side of the first gate insulating layer away from the gate, an orthographic projection of at least the channel on the substrate is located in an orthographic projection of the gate on the substrate, and the source and the drain are disposed on a side of the first gate insulating layer away from the substrate and respectively connected to the first contact portion and the second contact portion.

18. The array substrate according to claim 16, wherein the channel is a semiconductor, and the first contact portion and the second contact portion are conductors; and
the channel comprises the metal oxide conductive material and the electrical regulating element doped in the metal oxide conductive material, and the first contact portion and the second contact portion each comprise the metal oxide conductive material, and the electrical regulating element and a conductive element doped in the metal oxide conductive material.

19. The array substrate according to claim 1, wherein a metal atomic ratio of the electrical regulating element in the one or more first sublayers is greater than or equal to 0.1% and less than or equal to 10%,
a carrier concentration of the one or more first sublayers is greater than or equal to 1E14 cm⁻³ and less than or equal to 5E19 cm⁻³;
a resistance of the one or more first sublayers is greater than or equal to 1E4 Ω/□ and less than or equal to 1E10 Ω/□; and
a Hall mobility of the one or more first sublayers is greater than or equal to 30 cm²/V•s and less than or equal to 70 cm²/V•s.

20. A display panel comprising an array substrate comprising a semiconductor device, wherein the semiconductor device comprises:
an active layer;
a gate disposed on a side of the active layer; and
a source and a drain respectively connected to opposite ends of the active layer;
wherein the active layer comprises one or more first sublayers, each of the first sublayers comprises a metal oxide conductive material and an electrical regulating element doped in the metal oxide conductive material, and the electrical regulating element comprises at least one of Group VIII metal elements.
